(19) United States
(12) Patent Application Publication
(10) Pub. No.: US 2015/0341543 A1
(43) Pub. Date: Nov. 26, 2015

(54) IMAGE PICKUP APPARATUS, METHOD OF CONTROLLING THE SAME, AND NON-TRANSITORY COMPUTER-READABLE STORAGE MEDIUM

(71) Applicant: CANON KABUSHIKI KAISHA, Tokyo (JP)

(72) Inventors: Makoto Yokozeki, Tokyo (JP); Kazunori Ishii, Yokohama-shi (JP); Daisuke Ishikawa, Yokohama-shi (JP)

(21) Appl. No.: 14/710,112

(22) Filed: May 12, 2015

(30) Foreign Application Priority Data
May 20, 2014 (JP) 2014-104153

(51) Int. Cl. H04N 5/232

(52) U.S. Cl. CPC H04N 5/23212; H04N 5/23229

(57) ABSTRACT

An image pickup apparatus includes a calculator configured to detect a defocus amount based on a contrast evaluation value of a synthesized signal, wherein the synthesized signal is obtained by relatively shifting phases of passband signals of first and second signals through a predetermined frequency band and by synthesizing the passband signals, and a controller capable of changing the predetermined frequency band.

### BACKGROUND OF THE INVENTION

1. Field of the Invention

The present invention relates to an image pickup apparatus that performs focusing based on a contrast evaluation value.

2. Description of the Related Art

Japanese Patent Laid-open No. 2013-25246 discloses an image pickup apparatus that simultaneously executes an imaging-plane phase difference AF and a contrast AF to achieve fast focusing, which is an advantage of the imaging-plane phase difference AF, and rigorous focusing, which is an advantage of the contrast AF.

However, the image pickup apparatus of Japanese Patent Laid-open No. 2013-25246 is based only on a condition that a filter band for calculating a contrast evaluation value is set to be higher than that of a filter for the imaging-plane phase difference AF. Thus, the image pickup apparatus may fail to achieve a sufficient focus accuracy, focusing on a target object, and outputting of a correct focus direction to achieve an in-focus state from a defocus state.

For example, when fine focusing is required near the in-focus state, outputting the contrast evaluation value at a low frequency band fails to achieve a sufficient focus accuracy. On the other hand, when the focus direction needs to be acquired in the defocus state, outputting the contrast evaluation value at a high frequency band fails to obtain a correct focus direction.

### SUMMARY OF THE INVENTION

The present invention provides an image pickup apparatus capable of performing highly accurate focusing, a method of controlling the same, and a non-transitory computer-readable storage medium.

An image pickup apparatus as one aspect of the present invention includes a calculator configured to detect a defocus amount based on a contrast evaluation value of a synthesized signal, the synthesized signal being obtained by relatively shifting phases of passband signals of a first signal and a second signal through a predetermined frequency band and synthesizing the passband signals, and a controller that can change the predetermined frequency band.

A method of controlling an image pickup apparatus as another aspect of the present invention includes the step of detecting a defocus amount based on a contrast evaluation value of a synthesized signal, the synthesized signal is obtained by relatively shifting phases of passband signals of first and second signals through a predetermined frequency band and by synthesizing the passband signals, and the predetermined frequency band is variable.

A non-transitory computer-readable storage medium as another aspect of the present invention stores a program that causes a computer to execute a method of controlling an image pickup apparatus, the control method includes the step of detecting a defocus amount based on a contrast evaluation value of a synthesized signal, the synthesized signal is obtained by relatively shifting phases of passband signals of first and second signals through a predetermined frequency band and by synthesizing the passband signals, and the predetermined frequency band is variable.

Further features and aspects of the present invention will become apparent from the following description of exemplary embodiments with reference to the attached drawings.

### BRIEF DESCRIPTION OF THE DRAWINGS

FIG. 1 is a block diagram of a configuration of an image pickup apparatus according to an embodiment of the present invention.

FIG. 2 is a schematic diagram of a pixel array of an image pickup element included in an image pickup apparatus according to a first embodiment of the present invention.

FIGS. 3A and 3B are a schematic plan view and a schematic cross-sectional view of a pixel configuration of the image pickup element included in the image pickup apparatus according to the first embodiment of the present invention.

FIG. 4 illustrates correspondence between pixels and pupil division regions of the image pickup element included in the image pickup apparatus according to the first embodiment of the present invention.

FIG. 5 illustrates pupil division of an image pickup optical system and the image pickup element that are included in the image pickup apparatus according to the first embodiment of the present invention.

FIG. 6 illustrates a relation between defocus amounts and an image shift amount of an image based on a first focus detection signal and a second focus detection signal generated from a pixel signal from the image pickup element included in the image pickup apparatus according to the first embodiment of the present invention.

FIG. 7 is a schematic explanatory diagram of refocus processing in the first embodiment of the present invention.

FIG. 8 illustrates an example of a filter frequency band in the first embodiment of the present invention.

FIG. 9 illustrates an example of a contrast evaluation value calculated from a refocus signal in the first embodiment of the present invention.

FIG. 10 illustrates a flowchart of an operation of a first focus detection in the first embodiment of the present invention.

FIG. 11 illustrates a flowchart of an operation of a second focus detection in the first embodiment of the present invention.

FIG. 12 is a flowchart of an operation of focus processing in the first embodiment of the present invention.

FIG. 13 illustrates a flowchart of an operation of calculation of a first evaluation value in the first embodiment of the present invention.

FIG. 14 illustrates a flowchart of an operation of calculation of the first evaluation value in a second embodiment of the present invention.

FIG. 15 illustrates a flowchart of an operation of calculation of the first evaluation value in a third embodiment of the present invention.

FIG. 16 illustrates a flowchart of an operation of focus processing in a fourth embodiment of the present invention.

FIGS. 17A to 17C each illustrate a flowchart of an operation of calculation of the first evaluation value in the fourth embodiment of the present invention.

FIG. 18 is a schematic diagram of a pixel array in a fifth embodiment of the present invention.

FIGS. 19A and 19B are a schematic plan view and a schematic cross-sectional view of a pixel in the fifth embodiment of the present invention.

### DESCRIPTION OF THE EMBODIMENTS

Exemplary embodiments of the present invention will be described below with reference to the accompanied drawings. It is to be understood that the invention described with reference to the exemplary embodiments is not limited thereto. The scope of the following embodiments is to be accorded the broadest interpretation so as to encompass all such modifications and equivalent structures and functions.

### Embodiment 1

### Entire Configuration

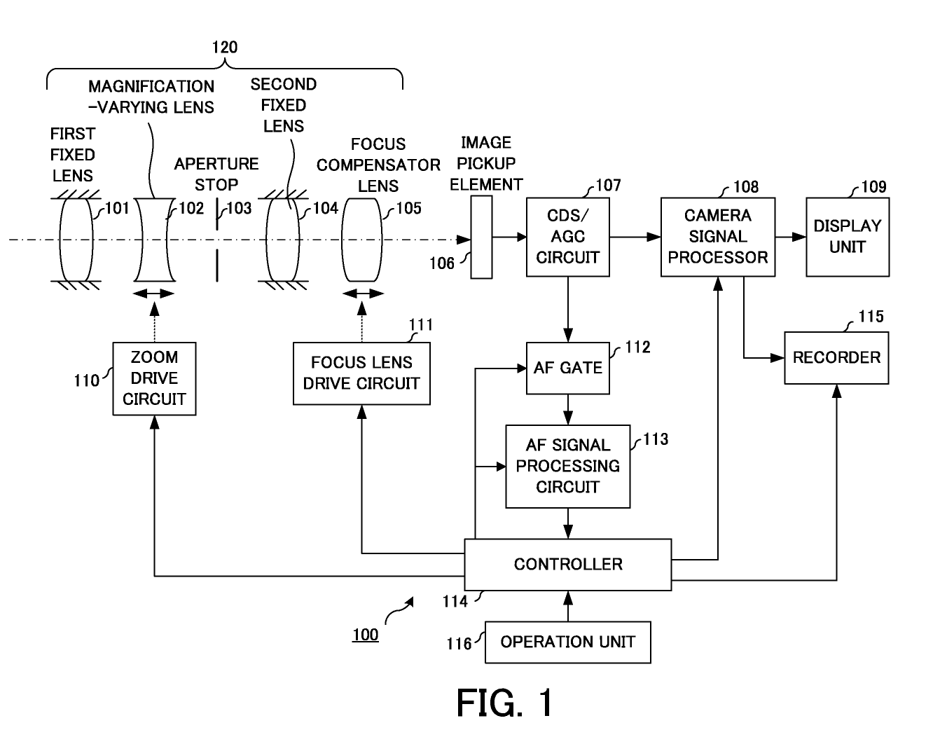

FIG. 1 is a block diagram of a configuration of an image pickup apparatus including a focusing apparatus according to a first embodiment of the present invention, illustrating a configuration diagram of a digital video camera as an example. Hereinafter, the image pickup apparatus (optical apparatus) according to the present embodiment of the present invention is exemplified by a lens-integrated image pickup apparatus including a camera body and a lens apparatus that are integrally formed, but the present invention is not limited thereto. For example, a lens interchangeable image pickup apparatus including a lens interchangeable digital single-lens reflex camera (camera body) and an interchangeable lens (lens apparatus) may be employed instead. As described later, the image pickup apparatus includes an image pickup element including a micro lens as a pupil division unit of an exit pupil of an image pickup optical system, and is capable of performing an imaging-plane phase difference focusing.

In FIG. 1, a digital video camera 100 according to the present embodiment includes a zoom lens 120 as the image pickup optical system having an autofocus function. The zoom lens 120 includes a first fixed lens 101, a magnification-varying lens 102 that moves in an optical axis direction to vary magnification, an aperture stop 103, a second fixed lens 104, and a focus compensator lens 105. The focus compensator lens (hereinafter, simply referred to as a focus lens) 105 has a function to correct movement of a focal plane due to magnification, and has a focusing function.

An image pickup element 106 includes a two-dimensional CMOS photo sensor and a peripheral and is disposed on an imaging plane of the image pickup optical system (imaging optical system).

A CDS/AGC circuit 107 performs correlated double sampling and gain adjustment on an output from the image pickup element 106.

A camera signal processor 108 performs various kinds of image processing on an output signal from the CDS/AGC circuit 107 to generate an image signal. A display unit 109 includes, for example, an LCD, and displays the image signal from the camera signal processor 108. A recorder 115 records the image signal from the camera signal processor 108 in a recording medium (magnetic tape, optical disk, and semiconductor memory, for example).

A zoom drive circuit 110 moves the magnification-varying lens 102 under control of a controller 114. A focus lens drive circuit 111 moves the focus lens 105 under control of the controller 114. The zoom drive circuit 110 and the focus lens drive circuit 111 each include an actuator such as a stepping motor, a DC motor, a vibration motor, and a voice coil motor.

An AF gate 112 supplies only those of output signals of all pixels from the CDS/AGC circuit 107, which are in a region (focus detection region or AF frame) for focus detection set by the controller 114, to an AF signal processing circuit 113 at a later stage.

The AF signal processing circuit 113 applies a filter on a signal of a pixel included in the focus detection region, which is supplied from the AF gate 112 so as to extract a high frequency component and generate an AF evaluation value. As described later, the AF signal processing circuit 113 in the present embodiment has a filter having a plurality of frequency characteristics, or a filter having a variable frequency characteristic. With this configuration, the AF signal processing circuit 113 generates the AF evaluation value through a filter having a frequency characteristic that differs depending on an output from a first focus detector described later. In this manner, the AF signal processing circuit 113 serves as a generator that generates the AF evaluation value (contrast evaluation value) based on a signal in a predetermined frequency band. The first focus detector is capable of detecting a focus state of the image pickup optical system, and is a focus detector that employs, for example, a phase difference detection method and a contrast detection method.

The AF evaluation value is output to the controller 114. The AF evaluation value indicates a sharpness (contrast) of an image generated based on an output signal from the image pickup element 106, and can used as a value representing the focus state of the image pickup optical system because the sharpness is high when the image is in focus and is low when the image is out of focus.

The controller 114 is, for example, a micro computer, and executes a control program previously stored in a ROM (not illustrated) to control each component in the digital video camera 100, and control an entire operation of the digital video camera 100. The controller 114 performs an AF control (automatic focusing control) operation by controlling the focus lens drive circuit 111 based on the AF evaluation value provided by the AF signal processing circuit 113. The controller 114 controls the zoom drive circuit 110 in accordance with a zoom instruction from an operation unit 116 to change the magnification of the zoom lens 120.

The operation unit 116 includes input devices such as a switch, a button, and a dial through which a user inputs various kinds of instructions and settings to the digital video camera 100. The operation unit 116 includes an image capturing start/stop button, a zoom switch, a still image capturing button, a directional button, a menu button, and an execution button.

### [Image Pickup Element]

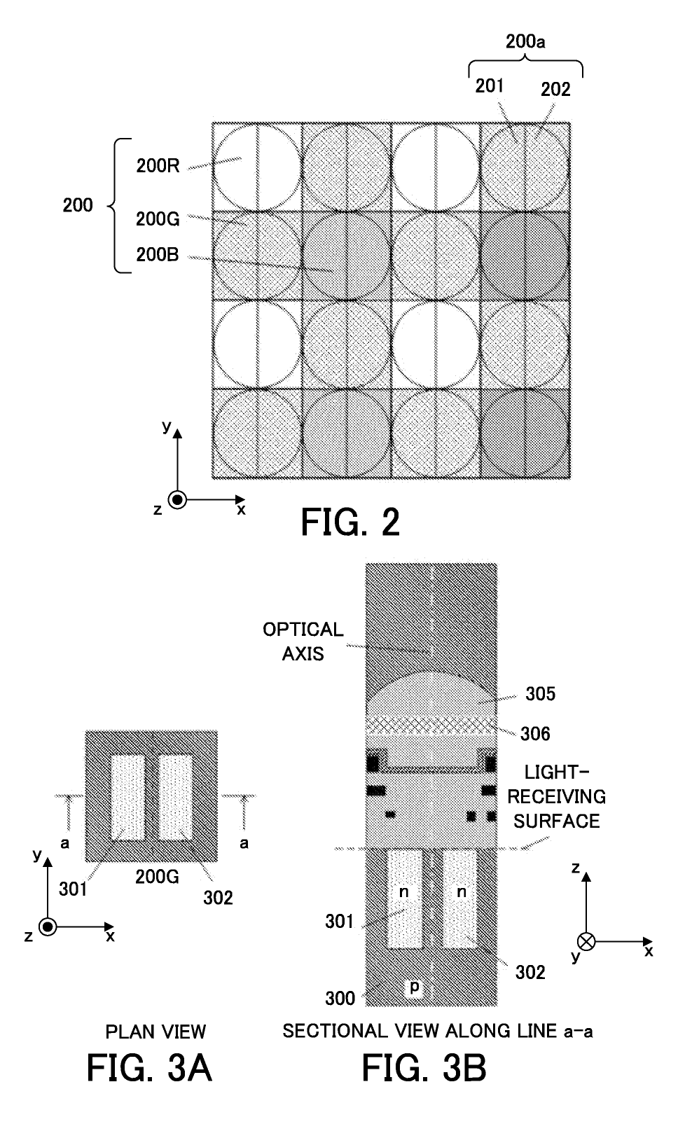

FIG. 2 is a schematic diagram of a pixel array of the image pickup element included in the image pickup apparatus according to the first embodiment. FIG. 2 illustrates a pixel array of 4×4 image pickup pixels (8×4 focus detection pixels) included in the two-dimensional CMOS sensor as the image pickup element that is used in the first embodiment.

In the present embodiment, a group 200 of 2×2 pixels illustrated in FIG. 2 includes a pixel 200R having red (R) spectral sensitivity at an upper-left position. The group 200 includes pixels 200G having green (G) spectral sensitivity at upper-right and lower-left positions. The group 200 includes a pixel 200B having blue (B) spectral sensitivity at a lower-right position. Each pixel (each image pickup pixel) 200a includes an array of 2×1 pixels of a first focus detection pixel 201 (first pixel) and a second focus detection pixel 202 (second pixel).

The image pickup element 106 includes a plurality of sets of 4×4 image pickup pixels (8×4 focus detection pixels) illustrated in FIG. 2 on the imaging plane so as to acquire image signals and focus detection signals. In the present embodiment, the image pickup element has a configuration in which the image pickup pixels are arranged at a period P of 4 μm, the number N thereof is 5575 columns×3725 rows=20,750,000 pixels approximately, the focus detection pixels are arranged at a period PAF of 2 μm in a column direction, and the focus detection number NAF thereof is 11150 columns×3725 rows=41,500,000 pixels approximately.

FIG. 3A is a plan view of the pixel 200G (image pickup pixel) of the image pickup element in FIG. 2 when viewed from a light-receiving surface of the image pickup element (in a positive z direction), and FIG. 3B is a sectional view along line a-a in FIG. 3A when viewed in a negative y direction.

As illustrated in FIGS. 3A and 3B, a micro lens 305 for condensing incident light is formed on a light-receiving surface side of pixels in the pixel 200G in the present embodiment, and a photoelectric converter 301 and a photoelectric converter 302 are formed through NH division (2 division) in an x direction and NV division (1 division) in a y direction. The photoelectric converters 301 and 302 respectively correspond to the first and second focus detection pixels 201 and 202.

The photoelectric converters 301 and 302 may be each a PIN structure photodiode including an intrinsic layer between a p-type layer 300 and a n-type layer, or a p-n junction photodiode with the intrinsic layer omitted as necessary.

Each pixel includes a color filter 306 formed between the micro lens 305 and the photoelectric converters 301 and 302. The color filter may have different spectral transmittances for different subpixels (focus detection pixels), or the color filter may be omitted, as necessary.

Light incident on the pixel 200G illustrated in FIGS. 3A and 3B is condensed through the micro lens 305 and dispersed through the color filter 306 and then is received by the photoelectric converters 301 and 302. The photoelectric converters 301 and 302 each generate pairs of an electron and a hole through photoelectric conversion depending on the quantity of the received light. The electron, which has negative electric charge, is separated through a depleted layer and then accumulated in the n-type layer. On the other hand, the hole is ejected out of the image pickup element through the p-type layer connected to a constant-voltage source (not illustrated). The electron accumulated in the n-type layer of each of the photoelectric converters 301 and 302 is transferred to a capacitor (FD) (not illustrated) through a transfer gate, and converted into a voltage signal to be output as a pixel signal.

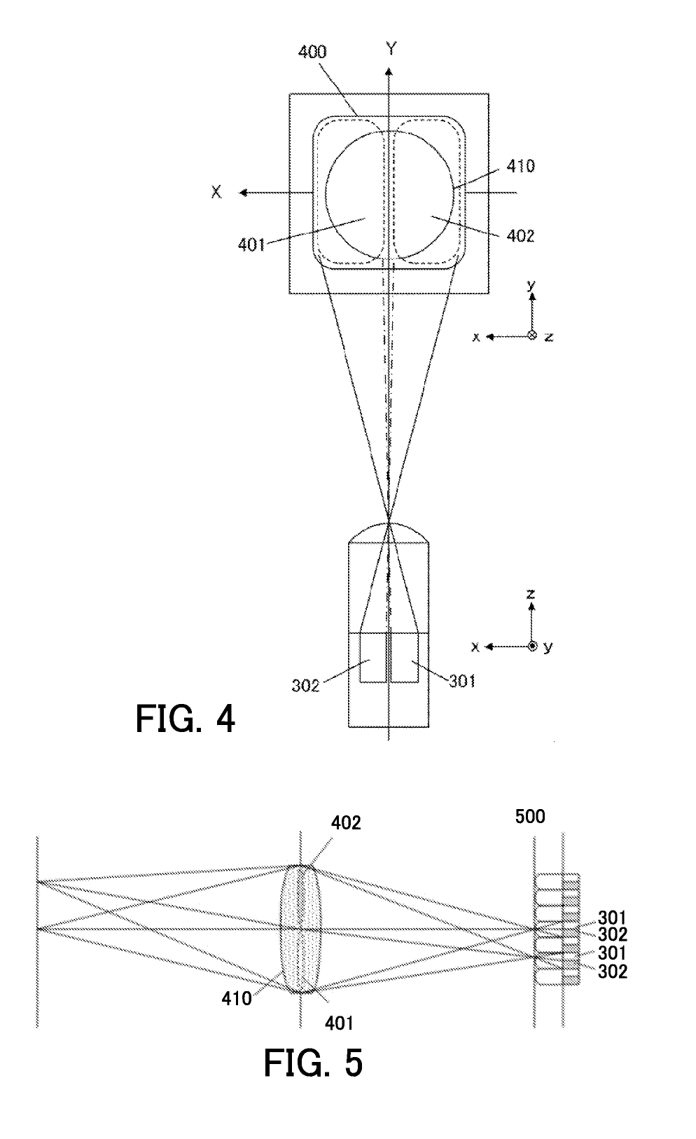

FIG. 4 illustrates a correspondence relation between the pixel structure in the present embodiment illustrated in FIGS. 3A and 3B and pupil division. FIG. 4 illustrates a sectional view along line a-a of the pixel structure in the first embodiment illustrated in FIG. 3A when viewed in a positive y direction and an exit pupil surface of the image pickup optical system. X and y axes in the sectional view of FIG. 4 are inverted with respect to those in FIGS. 3A and 3B so that they respectively correspond to coordinate axes of the exit pupil surface. FIG. 4 denotes the same components as those in FIGS. 3A and 3B with the same reference numerals.

As illustrated in FIG. 4, a first partial pupil region 401 of the first focus detection pixel 201 has a substantially conjugate relation with a light-receiving surface of the photoelectric converter 301 whose barycenter is decentered in a negative x direction with respect to the micro lens. The first partial pupil region 401 is a light-receiving pupil region of the first focus detection pixel 201. The first partial pupil region 401 of the first focus detection pixel 201 has a barycenter decentered in a positive x direction on the pupil surface. As illustrated in FIG. 4, a second partial pupil region 402 of the second focus detection pixel 202 has a substantially conjugate relation with a light-receiving surface of the photoelectric converter 302 whose barycenter is decentered in the positive x direction with respect to the micro lens. The second partial pupil region 402 is a light-receiving pupil region of the second focus detection pixel 202. The second partial pupil region 402 of the second focus detection pixel 202 has a barycenter decentered in the negative x direction on the pupil surface. In FIG. 4, a pupil region 400 is a light-receiving pupil region of the entire pixel 200G when the photoelectric converters 301 and 302 (first and second focus detection pixels 201 and 202) are combined.

FIG. 5 is schematic diagram of a correspondence relation between the image pickup element in the present embodiment and pupil division through the micro lens (pupil division unit). Light beams passing through different partial pupil regions that are the first partial pupil region 401 and the second partial pupil region 402 of an exit pupil 410 are incident on pixels of the image pickup element at different angles, and received by the first and second focus detection pixels 201 and 202 that are formed through 2×1 division. The present embodiment illustrates an example in which the pupil region is divided into two regions in a horizontal direction, but the pupil region may be divided in a vertical direction as necessary.

As described above, the image pickup element used in the present embodiment includes the first focus detection pixel that receives a light beam passing through the first partial pupil region of the image pickup optical system, and the second focus detection pixel that receives a light beam passing through the second partial pupil region of the image pickup optical system that is different from the first partial pupil region. More specifically, the image pickup element includes the first and focus detection pixels that share the single micro lens and receive light beams passing through different pupil regions (the first and second partial pupil regions) of the image pickup optical system. The image pickup element further includes an array of image pickup pixels that receive light beams passing through a pupil region as a combination of the first and second partial pupil regions of the image pickup optical system. Each image pickup pixel of the image pickup element in the present embodiment includes the first and focus detection pixels. However, as necessary, the first and second focus detection pixels may be configured separately from the image pickup pixel and disposed in parts of the array of image pickup pixels.

In the present embodiment, a light-reception signal from the first focus detection pixel 201 of each pixel 200a of the image pickup element is collected to generate a first focus detection signal, and a light-reception signal from the second focus detection pixel 202 of each pixel 200a is collected to generate a second focus detection signal (by a focus detection signal generator), so as to perform a focus detection. The signals from the first and second focus detection pixels 201 and 202 are added for each pixel of the image pickup element to generate an image signal (image pickup image) at a resolution of the number N of effective pixels.

### [Relation Between Defocus Amounts and Image Shift Amount]

Next, a relation between an image shift amount and defocus amounts of the first and second focus detection signals acquired by the image pickup element used in the present embodiment will be described.

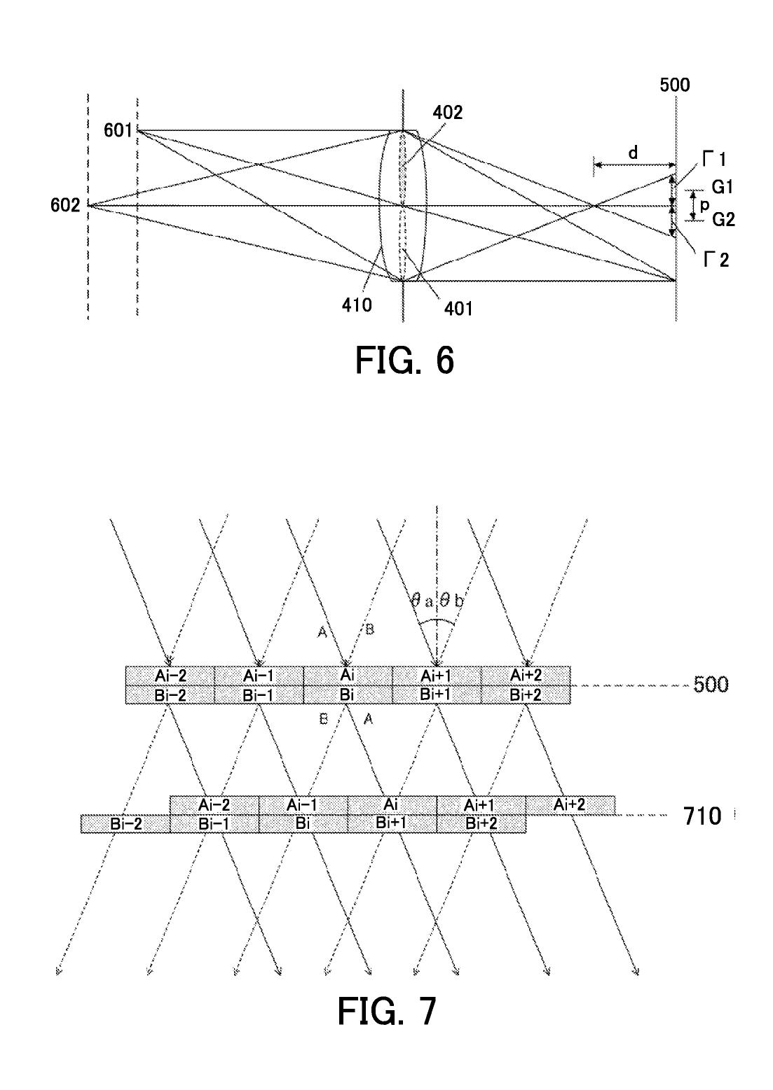

FIG. 6 illustrates the relation between the defocus amounts of the first and second focus detection signals and the image shift amount therebetween. The image pickup element (not illustrated) in the present embodiment is disposed on an imaging plane 500, and similarly to FIGS. 4 and 5, the exit pupil of the image pickup optical system is divided into two regions of the first and second partial pupil regions 401 and 402. FIG. 6 denotes the same components as those in FIGS. 3A, 3B, and 5 with the same reference numerals.

A defocus amount d is defined to be negative (d<0) for a short-focus state in which the imaging position of an object is between the imaging plane and the object, and to be positive (d>0) for an over-focus state in which the imaging position is opposite the object with respect to the imaging plane 500, where a size |d| is a distance from the imaging position of the object to the imaging plane 500. The defocus amount d is equal to zero for an in-focus state in which the imaging position of the object is at the imaging plane 500 (an in-focus position). FIG. 6 illustrates an exemplary in-focus state (d=0) with an object 601, and an exemplary short-focus state (d<0) with an object 602. The short-focus state (d<0) and the over-focus state (d>0) are collectively referred to as a defocus state (|d|>0).

In the short-focus state (d<0), among light beams from the object 602, an object light beam passing through the first partial pupil region 401 is condensed and then broadened to have a width Γ1 centering at a barycenter position G1, forming a blurred image on the imaging plane 500. Similarly, an object light beam passing through the second partial pupil region 402 is broadened to have a width Γ2 centering at a barycenter position G2, forming a blurred image. Each blurred image is received by the first focus detection pixel 201 (second focus detection pixel 202) included in each of the pixels arrayed in the image pickup element, to generate the first focus detection signal (second focus detection signal). Thus, the first focus detection signal (second focus detection signal) is recorded as a blurred object image of the object 602 having the width Γ1 (Γ2) at the barycenter position G1 (G2) on the imaging plane 500. The blur width Γ1 (Γ2) of the object image is mostly proportional to the size |d| of the defocus amount d. Similarly, a size |p| of an image shift amount p of the object image between the first and second focus detection signals (that is, a difference G1−G2 between the barycenter positions of the light beams) is mostly proportional to the size |d| of the defocus amount d. The over-focus state (d>0) has the same characteristics described above, although a direction of an image shift of the object image between the first and second focus detection signals is opposite to that of the short-focus state.

Therefore, as the sizes of the defocus amounts of the first and second focus detection signals, or the size of the defocus amount of an image signal as a sum of the first and second focus detection signals increases, the size of the image shift amount between the first and second focus detection signals increases.

### [Focus Detection]

In the present embodiment, a second focus detector described later uses the relation between the defocus amounts and the image shift amount of the first and second focus detection signals to perform a first focus detection by a method based on a refocus principle (hereinafter, referred to as a refocus method). The second focus detector also changes a filter band for an evaluation value used in the first focus detection by the refocus method, depending on a result of a second focus detection by a phase difference method.

A focusing state of an object is determined by comparing a predetermined value and a detected defocus amount in the present embodiment.

### [First Focus Detection by the Refocus Method]

First, the first focus detection by the refocus method in the present embodiment will be described.

In the first focus detection by the refocus method in the present embodiment, the AF signal processing circuit 113 relatively shifts the first and second focus detection signals and add them together to generate a shift addition signal (refocus signal). In other words, the AF signal processing circuit 113 serves as a refocus signal generator that performs refocus processing on the first focus detection signal obtained from the first focus detection pixel and the second focus detection signal obtained from the second focus detection pixel so as to generate the refocus signal. The AF signal processing circuit 113 then calculates the contrast evaluation value of the generated shift addition signal (refocus signal), and estimates an MTF peak position of the image signal based on the contrast evaluation value, thereby detecting a first detection defocus amount.

FIG. 7 illustrates the refocus processing in a one-dimensional direction (row direction, horizontal direction) based on the first and second focus detection signals acquired by the image pickup element of the present embodiment. FIG. 7 denotes the same components as those in FIGS. 5 and 6 with the same reference numerals. In a schematic diagram of FIG. 7, Ai and Bi respectively represent the first and second focus detection signals of an i-th pixel in the row direction that is included in the image pickup element and disposed on the imaging plane 500, where i represents an integer. The first focus detection signal Ai is the light-reception signal of a light beam incident on the i-th pixel at a primary light beam angle θa (corresponding to the partial pupil region 401 in FIG. 5). The second focus detection signal Bi is the light-reception signal of a light beam incident on the i-th pixel at a primary light beam angle θb (corresponding to the partial pupil region 402 in FIG. 5).

The first and second focus detection signals Ai and Bi include not only light intensity distribution information but also incident angle information. Thus, the refocus signal at a virtual imaging plane 710 can be generated by translating the first and second focus detection signals Ai and Bi at the respective angles θa and θb to the virtual imaging plane 710 and adding them together. The translation of the first focus detection signal Ai at the angle θa to the virtual imaging plane 710 corresponds to a shift of +0.5 pixel in the row direction, and the translation of the second focus detection signal Bi at the angle θb to the virtual imaging plane 710 corresponds to a shift of −0.5 pixel in the row direction. Therefore, the refocus signal at the virtual imaging plane 710 can be generated by shifting the first and second focus detection signals Ai and Bi relatively by +1 pixel and adding the first and second focus detection signals Ai and Bi+1 together. In this manner, the shift addition signal (refocus signal) at the virtual imaging plane corresponding to an amount of the integer multiple shift can be generated through a shift of the first and second focus detection signals Ai and Bi by an integer multiple of pixel and adding them together.

The first focus detection by the refocus method is performed by calculating the contrast evaluation value of the generated shift addition signal (refocus signal) and estimating the MTF peak position of the image signal based on the calculated contrast evaluation value.

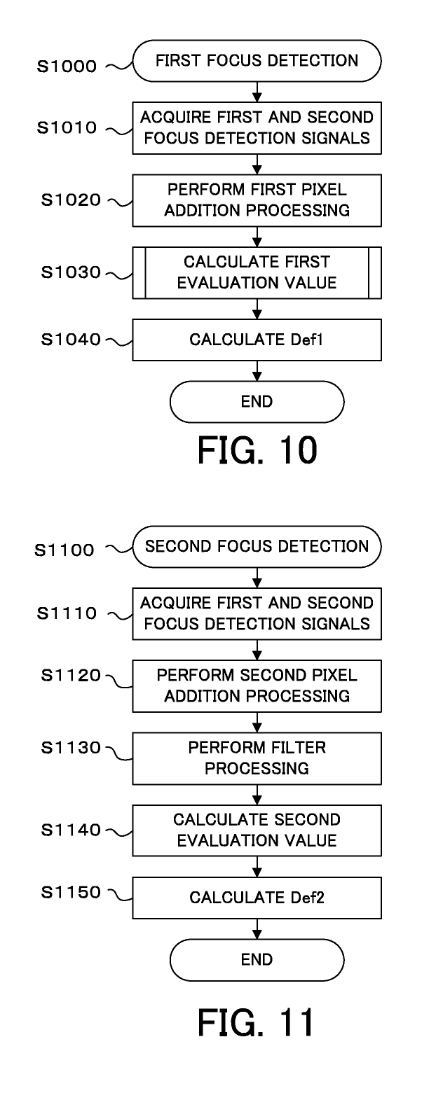

FIG. 10 illustrates a flowchart of an operation of the first focus detection in the first embodiment. The operation in FIG. 10 is executed by the image pickup element 106, the AF signal processing circuit 113, and the controller 114 (second focus detector) that controls them.

At step S1000, the operation starts.

At step S1010, the controller 114 first sets the focus detection region for focusing within a region of the effective pixels of the image pickup element. Then, the controller 114 controls drive of the image pickup element 106 to acquire, by the focus detection signal generator, the first focus detection signal based on the light-reception signal from the first focus detection pixel in the focus detection region, and the second focus detection signal based on the light-reception signal from the second focus detection pixel in the focus detection region.

At step S1020, the AF signal processing circuit 113 provides each of the first and second focus detection signals with three-pixel addition processing in the row direction to reduce a signal data amount, and then performs Bayer (RGB) addition processing to convert an RGB signal into a luminance Y signal. These two kinds of addition processing are collectively referred to as first pixel addition processing. One or both of the three-pixel addition processing and the Bayer (RGB) addition processing may be omitted as necessary.

At step S1030, the first and second focus detection signals are shifted relative to each other in a pupil division direction in first shift processing and added together to generate the shift addition signal (refocus signal). Then, the contrast evaluation value (a first evaluation value) based on the generated shift addition signal is calculated.

The calculation of the first evaluation value at step S1030 is a characteristic feature of the present embodiment and is performed based on a detection result of the first focus detector (employing the phase difference method) described later. The calculation of the first evaluation value will be described in detail later with reference to a flowchart in FIG. 13.

The k-th first focus detection signal is denoted by A(k), the k-th second focus detection signal is denoted by B(k), and a range of the number k corresponding to those signals from a pixel in the focus detection region is denoted by W. Where a shift amount by the first shift processing is denoted by s1 and a shift range of the shift amount s1 is denoted by Γ1, a contrast evaluation value (first evaluation value) RFCON is calculated by Expression (1) below.

$$RFCON ( s 1 ) = {max}_{k ∈ W} \vert A ( k ) + B ( k - s 1 ) \vert , s 1 ∈ Γ 1 \qquad ( 1 )$$

The k-th first focus detection signal A(k) and the (k−s1)-th second focus detection signal B(k−s1) correspond to each other through the first shift processing by the shift amount s1 and then are added together to generate the shift addition signal. The absolute value of the shift addition signal is calculated to obtain a maximum value in the range W of the focus detection region and calculate the contrast evaluation value (first evaluation value) RFCON(s1). The contrast evaluation value (first evaluation value) calculated for each row may be added together over a plurality of rows for each shift amount as necessary.

At step S1040, the contrast evaluation value (first evaluation value) is used in subpixel calculation to calculate a real-valued shift amount as a peak shift amount p1 at which the contrast evaluation value is at maximum. The peak shift amount p1 is multiplied with the image height of the focus detection region, the f-number of an image pickup lens (the image pickup optical system), and a first conversion coefficient K1 depending on an exit pupil distance, thereby calculating the first detection defocus amount (Def1).

In the present invention, the second focus detector employing the refocus method provides the first and second focus detection signals with the first shift processing, and then adds them together to generate the shift addition signal. Then, the shift addition signal is used to calculate the contrast evaluation value for the frequency band, and the calculated contrast evaluation value is used to detect the first detection defocus amount.

FIG. 9 illustrates examples of the contrast evaluation value (first evaluation value) calculated with different shift addition signals.

### [Second Focus Detection by the Phase Difference Method]

Next, the second focus detection by the phase difference method in the first embodiment will be described.

In the second focus detection by the phase difference method, the first and second focus detection signals are shifted relative to each other to calculate a correlation amount (second evaluation value) representing a degree of coincidence of the signals, thereby detecting the image shift amount based on a shift amount that leads to an improved correlation (the degree of coincidence of the signals). Since the image shift amount between the first and second focus detection signals increases as the defocus amount of the image signal increases, the image shift amount is converted into a second detection defocus amount when the focus detection is performed.

FIG. 11 illustrates a flowchart of an operation of the second focus detection in the first embodiment. The operation in FIG. 11 is executed by the image pickup element 106, the AF signal processing circuit 113, and the controller 114 (first focus detector) that controls them.

At step S1100, the operation starts.

At step S1110, the controller 114 first sets the focus detection region for focusing within a region of the effective pixels of the image pickup element. Then, the controller 114 controls drive of the image pickup element 106 to acquire the first focus detection signal based on the light-reception signal from the first focus detection pixel in the focus detection region, and the second focus detection signal based on the light-reception signal from the second focus detection pixel in the focus detection region.

At step S1120, the AF signal processing circuit 113 provides each of the first and second focus detection signals with the three-pixel addition processing in the row direction to reduce signal data amount, and then performs the Bayer (RGB) addition processing to covert an RGB signal into a luminance Y signal. These two kinds of addition processing are collectively referred to as second pixel addition processing.

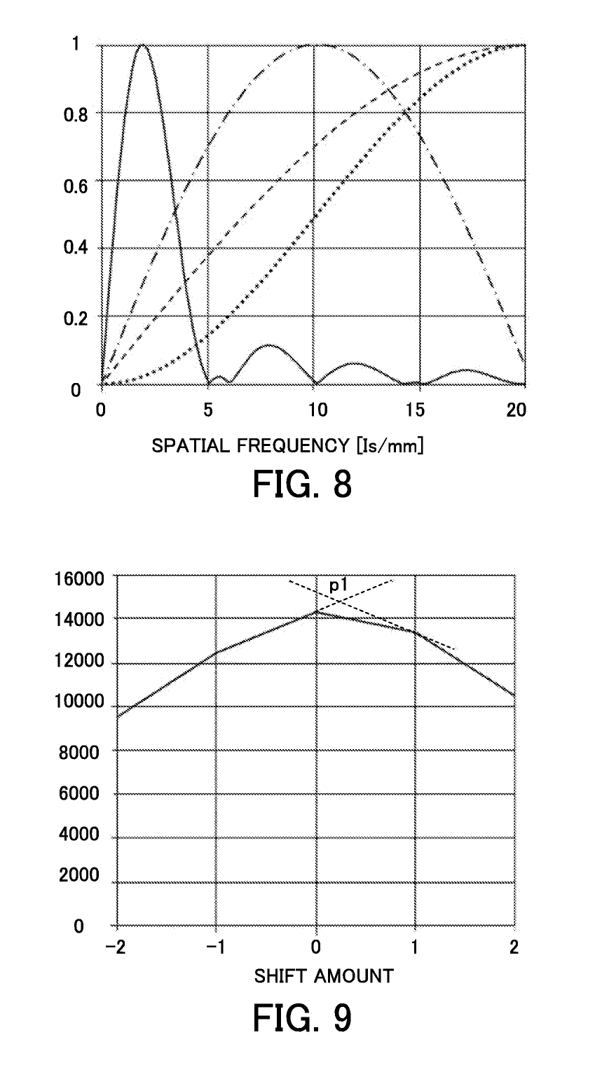

At step S1130 in FIG. 11, the first and second focus detection signals are provided with filter processing. FIG. 8 illustrates an example of a pass band of the filter processing in the present embodiment with a solid line. In the present embodiment, since focus detection in a large defocus state is performed through the second focus detection by the phase difference method, the pass band of the filter processing is set to include a low frequency band. When focusing is performed from the large defocus state to a small defocus state, the pass band of the filter processing in the second focus detection may be adjusted to include a higher frequency band depending on the defocus state as necessary, as illustrated with a dashed line in FIG. 8.

Next, at step S1140 in FIG. 11, the first and second focus detection signals after the filter processing are shifted relative to each other in the pupil division direction in second shift processing to calculate the correlation amount (second evaluation value) representing the degree of coincidence of the signals.

The k-th first and second focus detection signals after the filter processing are denoted by A(k) and B(k), and a range of the number k corresponding to those signals from a pixel in the focus detection region is denote by W. Where a shift amount by the second shift processing is denoted by s2 and a shift range of the shift amount s2 is Γ2, a correlation amount (second evaluation value) COR is calculated by Expression (2) below.

$$COR ( s 2 ) = {\sum }_{k ∈ W} \vert A ( k ) - B ( k - s 2 ) \vert , s 2 ∈ Γ 2 \qquad ( 2 )$$

The k-th first focus detection signal A(k) and the (k−s2)-th second focus detection signal B(k−s2) correspond to each other through the second shift processing by the shift amount s2 and then are subtracted to generate a shift subtraction signal. The absolute value of the generated shift subtraction signal is calculated and summed over the number k in the range W of the focus detection region to calculate the correlation amount (second evaluation value) COR(s2). The correlation amount (second evaluation value) calculated for each row may be added together over a plurality of rows for each shift amount as necessary.

At step S1150, the correlation amount (second evaluation value) is used in subpixel calculation to calculate a real-valued shift amount as an image shift amount p2 at which the correlation amount is at minimum. The image shift amount p2 is multiplied with the image height of the focus detection region, the f-number of the image pickup lens (image pickup optical system), and a second conversion coefficient K2 depending on the exit pupil distance, thereby calculating the second detection defocus amount (Def2).

The first and second conversion coefficients K1 and K2 may be identical to each other as necessary.

As described above, in the present embodiment, the first focus detector employing the phase difference method provides the first and second focus detection signals with the filter processing and the second shift processing to calculate the correlation amount, thereby detecting the second detection defocus amount based on the correlation amount.

### [First Evaluation Value Calculation]

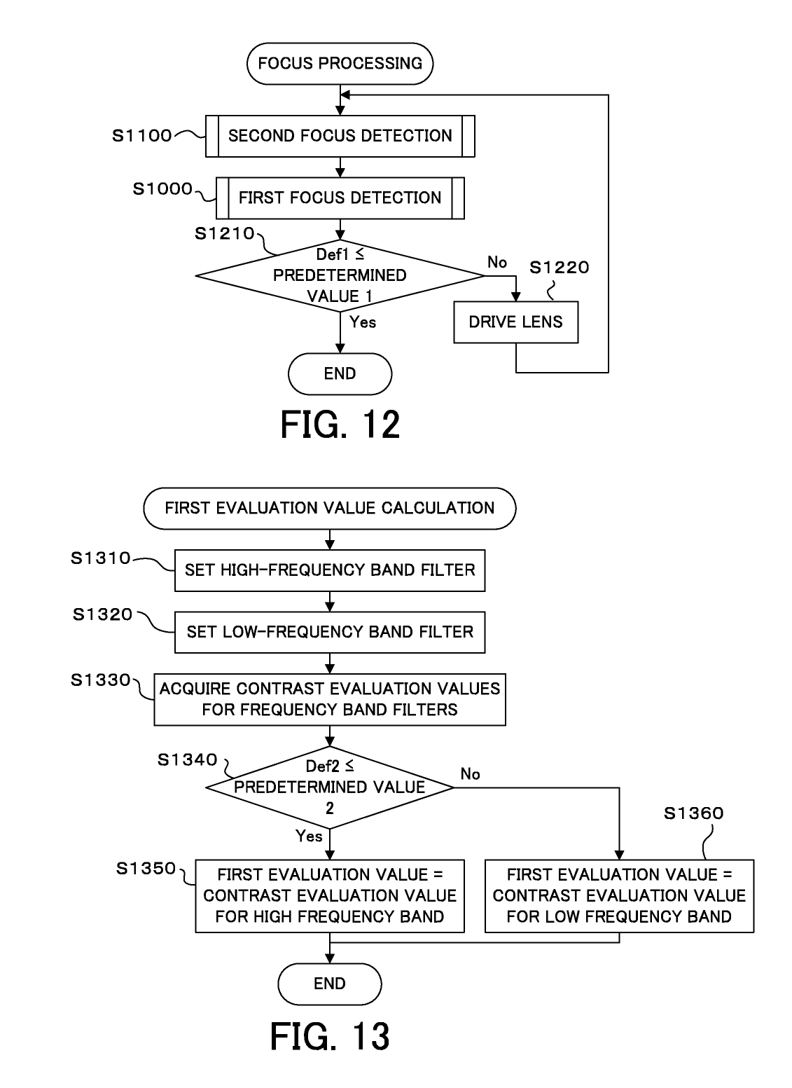

Details of the filter processing at step S1130 and the first evaluation value calculation at step S1030 described above will be described with reference to flowcharts in FIGS. 12 and 13.

Operations in FIGS. 12 to 13 are executed by the image pickup element 106, the AF signal processing circuit 113, and the controller 114 that controls them.

In the first embodiment, until the absolute value of the defocus amount of the image pickup optical system becomes not larger than a predetermined value 1, the first focus detection by the refocus method is performed to drive a lens, thereby performing focus processing until a best in-focus position is nearly achieved.

First, referring to FIG. 12, the focus processing according to the present embodiment will be described.

At step S1100, the second focus detection by the phase difference method described with reference to FIG. 11 is performed, and the flow proceeds to step S1000.

Next, at step S1000, the first focus detection by the refocus method described with reference to FIG. 10 is performed, and the flow proceeds to step S1210.

Next, at step S1210, it is determined whether the first defocus amount (Def1) calculated at step S1000 is not larger than the predetermined value 1.

When the size |Def1| of the detected first defocus amount is not larger than the predetermined value 1, focusing is determined to be complete, and the focus processing is finished. On the other hand, when the size |Def1| is larger than the predetermined value 1, the lens drive at step S1220 is performed depending on the first defocus amount (Def1), and the flow returns to step S1100. In this manner, the controller 114 serves as a controller that performs focusing based on the calculated defocus amount.

Next, the calculation of the first evaluation value at step S1030 in FIG. 10 will be described in detail with reference to FIG. 13.

In FIG. 13, the calculation of the first evaluation value starts by setting a high-frequency band filter (filter for a first frequency band) at step S1310, and the flow proceeds to step S1320.

Next, at step S1320, a low-frequency band filter (filter for a second frequency band) for a frequency band lower than that of the high-frequency band filter set at step S1320 is set.

Examples the frequency bands described above are illustrated with a broken line and a dashed line in FIG. 8. A filter for a frequency band illustrated with a dotted line in FIG. 8 may be set in place of a filter for the frequency band illustrated with the broken line in FIG. 8.

Although only the two filters of the high-frequency band filter and the low-frequency band filter are set in FIG. 13, three frequency band filters or more may be set. Moreover, although a filter to be set in the present embodiment is different from the frequency band filter used in the filter processing in the second focus detection by the phase difference method, the same frequency band filter used in the filter processing may be used.

Next, at step S1330, the contrast evaluation values based on passband signals through the frequency band filters set at steps S1310 and S1320 is acquired, and the flow proceeds to step S1340.

Next, at step S1340, it is determined whether the second defocus amount (Deft) calculated at step S1100 and detected by the phase difference detection method is not larger than a predetermined value 2.

When the size |Def2| of the detected second defocus amount is not larger than the predetermined value 2, the flow proceeds to step S1350. On the other hand, when the size |Def2| is larger than the predetermined value 2, the flow proceeds to step S1360.

Next, at step S1350, the first evaluation value is set to be the contrast evaluation value based on passband signals through the high-frequency band filter, and the calculation of the first evaluation value is finished. In other words, when the size |Def2| of the second defocus amount is not larger than the predetermined value 2 (a first predetermined value), the contrast evaluation value is generated based on the passband signals through the high frequency band (first frequency band).

At step S1360, the first evaluation value is set to be the contrast evaluation value based on passband signals through the low-frequency band filter, and the calculation of the first evaluation value is finished. In other words, when the size |Def2| of the second defocus amount is larger than the predetermined value 2 (first predetermined value), the contrast evaluation value is generated based on the passband signals through the low frequency band (second frequency band).

In this manner, in the present embodiment, the first evaluation value is generated from passband signals through one of the first frequency band and the second frequency band lower than that of the first frequency band, which is selected based on the detection result (Deft) of the focus detector employing the phase difference detection method.

The configuration described above enables an appropriate frequency band filter to be set based on the detection result of the second focus detection by the phase difference method when focusing is performed through the first focus detection by the refocus method, thereby achieving fast and stable (that is, highly accurate) focusing. In the present embodiment, the image pickup pixels are divided in the horizontal direction, but a similar operation is achievable also with the division in the vertical direction.

### Embodiment 2

Next, a second embodiment of the present invention will be described. First, differences between the present embodiment and the first embodiment will be described.

The present embodiment employs a method different from the method of calculating the first evaluation value described as the characteristic of the first embodiment. In the first embodiment, the contrast evaluation value acquired from the AF signal processing circuit 113 is selected from the contrast evaluation value based on passband signals through the high-frequency band filter and the contrast evaluation value based on passband signals through the low-frequency band filter. In the second embodiment, the contrast evaluation value is generated as a weighted sum of both (two or more, for three filters or more) of the contrast evaluation values with predetermined weights.

The digital video camera 100 in the present embodiment has the same configuration as that described with reference to FIG. 1 in the first embodiment, and thus description thereof will be omitted.

The operations of the digital video camera 100 described with reference to the flowcharts in FIGS. 10 to 12 in the first embodiment are the same in the present embodiment, and thus description thereof will be omitted.

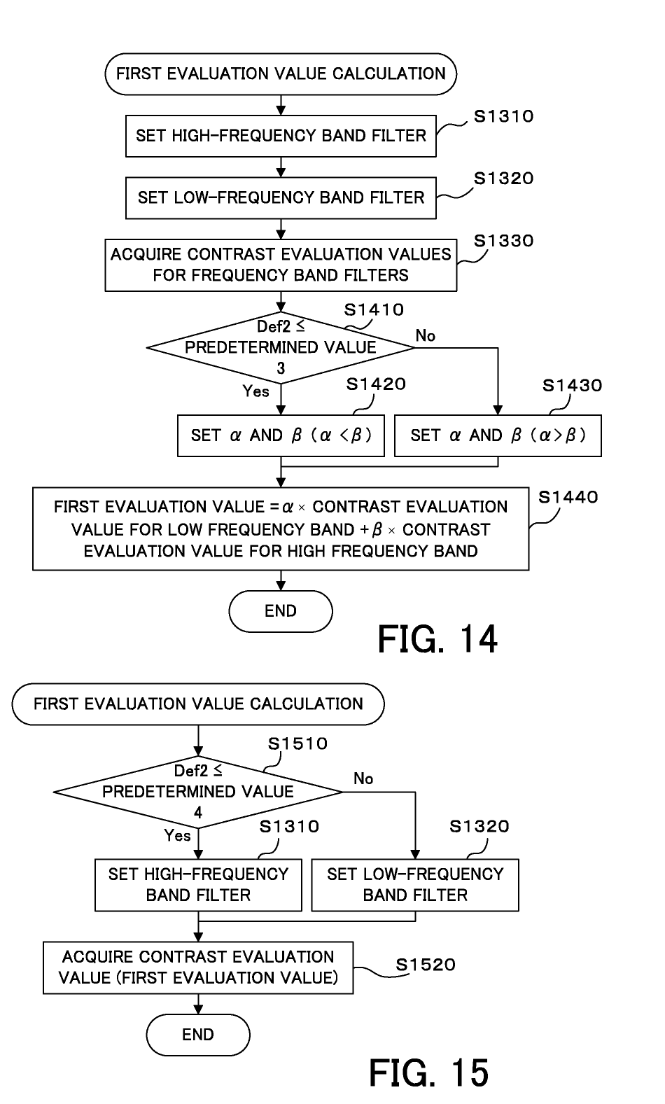

A characteristic feature of the second embodiment will be described with reference to FIG. 14. The same processes as those in the first embodiment will be denoted by the same reference numerals, and descriptions thereof will be omitted.

At step S1410, it is determined whether the second defocus amount (Def2) calculated at step S1100 and detected by the phase difference method is not larger than a predetermined value 3.

When the size |Def2| of the detected second defocus amount is not larger than the predetermined value 3, the flow proceeds to step S1420. On the other hand, when the size |Def2| is larger than the predetermined value 3, the flow proceeds to step S1430.

At steps S1420 and S1430, coefficients α and β that multiply a plurality of evaluation values when they are added together are set.

In the second embodiment, when the size |Def2| of the second defocus amount is not larger than the predetermined value 3 (a second predetermined value), a fourth contrast evaluation value is generated as a product of the contrast evaluation value for the high frequency band (first frequency band) with the weight β (a third weight). On the other hand, a fifth contrast evaluation value is generated as a product of the contrast evaluation value for the low frequency band (second frequency band) with the weight α (a fourth weight) smaller than the weight β. Then, the first defocus amount is detected based on a sixth contrast evaluation value as a sum of the fourth and fifth contrast evaluation values. Thus, at step S1420, α and β are set to such values that α is smaller than β.

On the other hand, in the second embodiment, when the size |Def2| of the second defocus amount is larger than the predetermined value 3 (second predetermined value), a first contrast evaluation values is generated as a product of the contrast evaluation value for the high frequency band (first frequency band) with the weight β (a first weight). In addition, a second contrast evaluation value is generated as a product of the contrast evaluation value for the low frequency band (second frequency band) with the weight α (a second weight) larger than the weight β. Then, the first defocus amount is detected based on a third contrast evaluation value as a sum of the first and second contrast evaluation values. Thus, at step S1430, α and β are set to such values that α is larger than β.

Thus, when it is determined that the second defocus amount is large, that is, the current lens position is far from the in-focus position, which is generating a blurred image, a focusing point and a focusing direction can be more accurately calculated based on the contrast evaluation value for the low frequency band.

On the other hand, when the second defocus amount is small, that is, the current lens position is close to the in-focus position, the focusing point and the focusing direction can be more accurately calculated based on the contrast evaluation value for the high frequency band.

Next, at step S1440, the first evaluation value is generated as a sum of the contrast evaluation value for the low frequency band and the contrast evaluation value for the high frequency band based on the values of α and β set at step S1420 or step S1430.

The first evaluation value is calculated by Expression (3) below.

FIRST EVALUATION VALUE=α×CONTRAST EVALUATION VALUE FOR LOW FREQUENCY BAND+β×CONTRAST EVALUATION VALUE FOR HIGH FREQUENCY BAND (3)

In the present embodiment, α and β are set to satisfy a condition α+β=1, and α is set to be larger for a larger second defocus amount (Def2) detected by the phase difference method, whereas β is set to be larger for a smaller second defocus amount (Def2). In this manner, in the present embodiment, the weight α and the weight β are changed based on the detection result (Def2) of the first focus detector.

The ratio of the values of α and β for the size of the second defocus amount (Def2) can be set to be any values as long as the values satisfy the condition. In the present embodiment, α and β are set to be such linear changing values that α=0 and β=1 for the second defocus amount (Def2)=0, and α=1 and β=0 for the second defocus amount (Def2) being at a predetermined maximum defocus amount.

As described above, in the present embodiment, when |Def2| is larger than the predetermined value 3, the first contrast evaluation value is generated as a product of a contrast evaluation value generated from a passband signal through the high frequency band with the first weight β. The second contrast evaluation value is generated as a product of a contrast evaluation value generated from a passband signal through the low frequency band with the second weight α larger than the first weight β, and then the third contrast evaluation value is generated as a sum of the first and second contrast evaluation values. On the other hand, when |Def2| is not larger than the predetermined value 3, the fourth contrast evaluation value is generated as a product of a contrast evaluation value generated from a passband signal through the high frequency band with the third weight β. The fifth contrast evaluation value is generated as a product of a contrast evaluation value generated from a passband signal through the low frequency band with a fourth weight α smaller than the third weight β, and then the sixth contrast evaluation value is generated as a sum of the fourth and fifth contrast evaluation values.

The configuration described above allows an appropriate frequency band filter to be set based on the detection result of the second focus detection by the phase difference method when focusing is performed through the first focus detection by the refocus method, thereby achieving fast and stable (that is, highly accurate) focusing.

### Embodiment 3

Next, a third embodiment of the present invention will be described. First, differences between the present embodiment and the first and second embodiments will be described.

The present embodiment employs a method different from the method of calculating the first evaluation value described as the characteristic features of the first and second embodiments.

In the first embodiment, the contrast evaluation value acquired from the AF signal processing circuit 113 is selected from the contrast evaluation value based on passband signals through the high-frequency band filter and the contrast evaluation value based on passband signals through the low-frequency band filter.

In the second embodiment, the contrast evaluation value is generated as a weighted sum of both (two or more, for three filters or more) of the contrast evaluation values with the predetermined weights.

In the third embodiment, the frequency band of a filter set to the AF signal processing circuit 113 is switched depending on the second defocus amount.

The digital video camera 100 in the present embodiment has the same configuration as that described with reference to FIG. 1 in the first embodiment, and thus description thereof will be omitted.

The operation of the digital video camera 100 described with reference to the flowcharts in FIGS. 10 to 12 in the first embodiment is the same in the present embodiment, and thus description thereof will be omitted.

A characteristic feature of the third embodiment will be described with reference to FIG. 15. The same processes as those in the first embodiment will be denoted by the same reference numerals, and descriptions thereof will be omitted.

At step S1510, it is determined whether the second defocus amount (Def2) calculated at step S1100 and detected by the phase difference method is not larger than a predetermined value 4.

When the size |Def2| of the detected second defocus amount is not larger than the predetermined value 4, the flow proceeds to step S1310 to set the high-frequency band filter. On the other hand, when the size |Def2| is larger than the predetermined value 4, the flow proceeds to step S1320 to set the low-frequency band filter.

Next, at step S1520, the contrast evaluation value based on passband signals through the filter set at step S1310 or at step S1320 is acquired as the first evaluation value.

In this manner, in the present embodiment, the first evaluation value is generated from passband signals through one of the first frequency band and the second frequency band lower than the first frequency band, which is selected based on the detection result (Deft) of the focus detector employing the phase difference detection method.

When focusing is performed through the first focus detection by the refocus method, the configuration described above allows an appropriate frequency band filter to be set based on the detection result of the second focus detection by the phase difference method, and allows the first defocus amount to be calculated from the contrast evaluation value based on passband signals through the frequency band filter. This enables fast and stable (that is, highly accurate) focusing.

### Embodiment 4

Next, a fourth embodiment of the present invention will be described. First, differences between the present embodiment and the first, second, and third embodiments will be described.

The present embodiment employs a method different from the detection method employed by the second focus detector described as the characteristic features of the first, second, and third embodiments.

The digital video camera 100 in the present embodiment has the same configuration as that described with reference to FIG. 1 in the first embodiment, and thus description thereof will be omitted.

The operation of the digital video camera 100 described with reference to the flowcharts in FIGS. 10 to 11 in the first embodiment is the same in the present embodiment, and thus description thereof will be omitted.

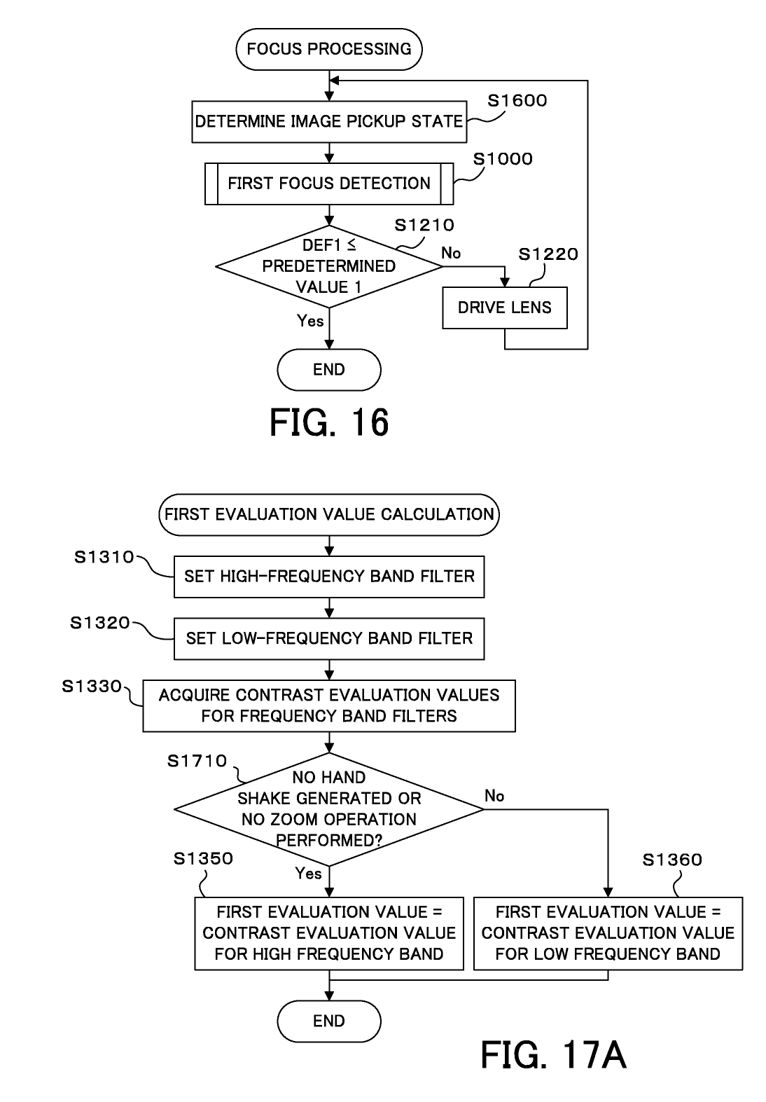

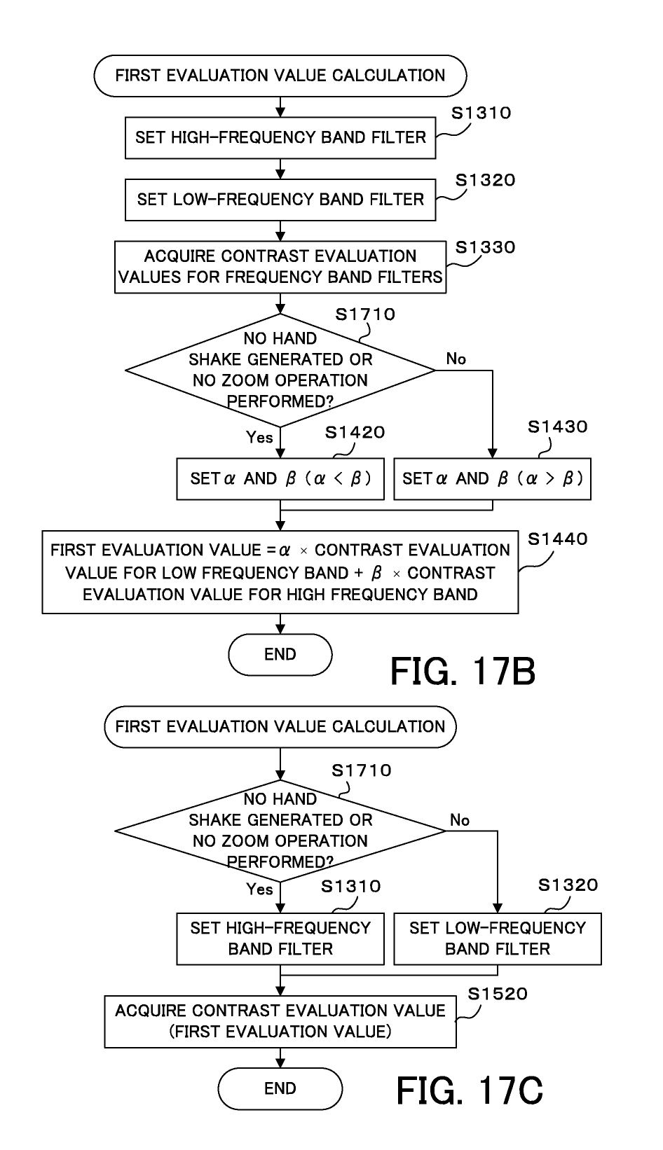

A characteristic feature of the fourth embodiment will be described with reference to FIGS. 16 and 17A to 17C. The same processes as those in the first or second embodiment will be denoted by the same reference numerals, and descriptions thereof will be omitted.

In FIG. 16, once focus processing is started, the flow proceeds to image pickup state determination at step S1600. Description of the subsequent processing will be omitted for the same reason given above.

The image pickup state determination at step S1600 determines whether the controller 114 has received information of generation of a hand shake from a hand shake detection sensor (not illustrated), or whether the controller 114 has received an instruction of an zoom operation from the operation unit 116. Thus, in the present embodiment, the controller 114 serves as a detector that detects an image pickup state such as a shaking state and a zooming state.

Next, three patterns of the first evaluation value calculation in the first focus detection at step S1000 will be described with reference to FIGS. 17A to 17C.

At step S1710 in FIG. 17A, when the image pickup state determination at step S1600 determines that no hand shake is generated or no zoom operation is performed, the flow proceeds to step S1350. On the other hand, when it is determined that a hand shake is detected or the zoom operation is performed, the flow proceeds to step S1360. In this manner, in the operation illustrated in FIG. 17A, the AF signal processing circuit 113 generates the contrast evaluation value based on passband signals through one of the high frequency band (first frequency band) and the low frequency band (second frequency band), which is selected based on the detection result of the detector. More specifically, having received an output signal from the controller 114 (detector), the AF signal processing circuit 113 generates the contrast evaluation value based on passband signals through the low frequency band (second frequency band). Having received no output signal from the controller 114 (detector), the AF signal processing circuit 113 generates the contrast evaluation value based on passband signals through the high frequency band (first frequency band).

At step S1710 in FIG. 17B, when the image pickup state determination at step S1600 determines that no hand shake is generated or no zoom operation is performed, the flow proceeds to step S1420. On the other hand, when it is determined that a hand shake is detected or the zoom operation is performed, the flow proceeds to step S1430. In this manner, in the operation illustrated in FIG. 17B, the AF signal processing circuit 113 generates the first contrast evaluation value based on the passband signals through the high frequency band and the weight β, and the second contrast evaluation value based on the passband signals through the low frequency band and the weight α. Then, the AF signal processing circuit 113 generates the third contrast evaluation value as a sum of the first and second contrast evaluation values. In the generation of the third contrast evaluation value, the weights α and β are changed based on the detection result of the controller 114 (detector). Specifically, when an output signal from the detector is received, the weight α is set to be larger than the weight β. On the other hand, when an output signal from the detector is not received, the weight α is set to be smaller than the weight β.

At step S1710 in FIG. 17C, when the image pickup state determination at step S1600 determines that no hand shake is generated or no zoom operation is performed, the flow proceeds to step S1310. On the other hand, when it is determined that a hand shake is detected or the zoom operation is performed, the flow proceeds to step S1320. In this manner, in the operation illustrated in FIG. 17C, similarly to FIG. 17A, the AF signal processing circuit 113 generates the contrast evaluation value based on passband signals through one of the high frequency band and the low frequency band, which is selected based on the detection result of the controller 114 (detector). However, the operation illustrated in FIG. 17C generates only the contrast evaluation value based on passband signals through the filter selected (set) based on the detection result of the detector, but not generates the contrast evaluation value based on passband signals through a filter not selected (set). Having received the output signal from the detector, the AF signal processing circuit 113 generates the contrast evaluation value based on the passband signals through the low frequency band. Having received no output signal from the detector, the AF signal processing circuit 113 generates the contrast evaluation value based on the passband signals through the high frequency band.

The operations illustrated in FIGS. 17A to 17C in the fourth embodiment have each determination made on whether a hand shake or the zoom operation is detected, but the determination may be made on a degree of hand shake and a speed of a view angle change due to zooming.

For example, in FIG. 17A, the contrast evaluation value for the low frequency band may be used when the degree of hand shake is larger than a predetermined value (third predetermined value), and the contrast evaluation value for the high frequency band may be used when the degree of hand shake is not larger than the third predetermined value. In other words, the contrast evaluation value is generated based on the passband signals through the low frequency band when the detector outputs a value larger than the third predetermined value, and the contrast evaluation value is generated based on the passband signals through the high frequency band when the detector outputs a value not larger than the third predetermined value.

In FIG. 17B, α and β may be calculated such that α is larger (β is smaller) when the degree of hand shake is larger than a predetermined value (fourth predetermined value) than when the degree of hand shake is not larger than the fourth predetermined value. In other words, the detector outputs a value larger than the fourth predetermined value, the weight α is set to be larger than the weight β. On the other hand, when the detector outputs a value not larger than the fourth predetermined value, the weight α is set to be smaller than the weight β.

Similarly, in FIG. 17C, the low-frequency band filter may be set when the degree of hand shake is larger than a predetermined value (fifth predetermined value), and the high-frequency band filter may be set when the degree of hand shake is not larger than the fifth predetermined value. In other words, the contrast evaluation value is generated based on the passband signals through the low frequency band when the detector outputs a value larger than the fifth predetermined value, and the contrast evaluation value is generated based on the passband signals through the high frequency band when the detector outputs a value not larger than the fifth predetermined value.

When focusing is performed through the first focus detection by the refocus method, the configuration described above allows an appropriate frequency band filter to be set based on the image pickup state such as the zooming state and the shaking state, and enables fast and stable (that is, highly accurate) focusing.

### Embodiment 5

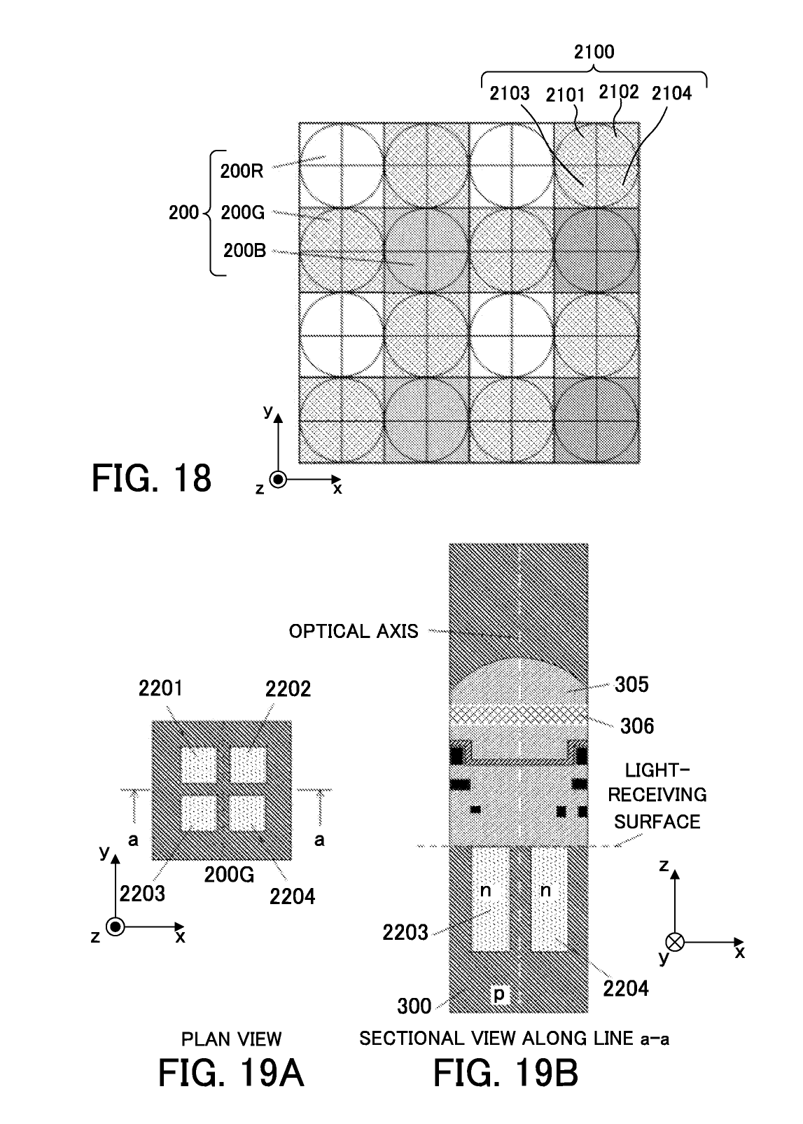

FIG. 18 is a schematic diagram of an array of image pickup pixels and subpixels of an image pickup element in the fifth embodiment of the present invention. FIG. 18 illustrates an array of 4×4 pixels (image pickup pixels) and an array of 8×8 subpixels (focus detection pixels) of a two-dimensional CMOS sensor (image pickup element) in the fifth embodiment. The same components as those in FIG. 2 are denoted by the same reference numerals. An image pickup apparatus in the present embodiment has the same configuration as that in the first embodiment except for the pixel configuration of the image pickup element, which will be described below.

In the present embodiment, as illustrated in FIG. 18, a group 200 of 2×2 pixels includes a pixel 200R having red (R) spectral sensitivity at an upper-left position, pixels 200G having green (G) spectral sensitivity at upper-right and lower-left positions, and a pixel 200B having blue (B) spectral sensitivity at a lower-right position. Each pixel includes an array of 2×2 subpixels 2101 to 2104.

The image pickup element is provided thereon with a plurality of arrays of 4×4 pixels (8×8 subpixels) illustrated in FIG. 18 to acquire a captured image (subpixel signals). In the present embodiment, the image pickup element has a period P of pixels of 4 μm, the number N of pixels of 5575 columns×3725 rows=20750000 pixels approximately, a period PSUB of subpixels of 2 μm, and the number NSUB of sub pixels of 11150 columns×7450 rows=83000000 pixels approximately.

FIG. 19A is a plan view of one pixel 200G in the image pickup element illustrated in FIG. 18 viewed from a light-receiving surface of the image pickup element (in the positive z direction), and FIG. 19B is a sectional view along line a-a in FIG. 19A when viewed in the negative y direction. FIGS. 19A and 19B denote the same components as those in FIGS. 3A and 3B with the same reference numerals.

As illustrated in FIGS. 19A and 19B, the micro lens 305 for condensing incident light is formed on the light-receiving surface side of pixels in the pixel 200G in the present embodiment, and photoelectric converters 2201 to 2204 are formed through NH division (2 division) in the x direction and NV division (2 division) in the y direction. The photoelectric converters 2201 to 2204 respectively correspond to subpixels 2101 to 2104.

In the present embodiment, signals from the subpixels 2101 to 2104 are added together for each pixel (2100) of the image pickup element to generate an image signal (captured image) having a resolution for the number N of effective pixels. In addition, the signals from the subpixels 2101 and 2103 are added together for each pixel to generate the first focus detection signal, and the signals from the subpixels 2102 and 2104 are added together to generate the second focus detection signal. These addition processes acquire the first and second focus detection signals corresponding to pupil division in the horizontal direction, which allows the first focus detection by the phase difference method and the second focus detection by the refocus method to be performed.

Similarly, in the present embodiment, signals from the subpixels 2101 and 2102 are added together for each pixel to generate the first focus detection signal, and the signals from the subpixels 2103 and 2104 are added together to generate the second focus detection signal. These addition processes acquire the first and second focus detection signals corresponding to pupil division in the vertical direction, which allows the first focus detection by the phase difference method and the second focus detection by the refocus method to be performed. In this manner, the image pickup element in the present embodiment can be used as the image pickup element of the image pickup apparatus in the first to fifth embodiments.

Other configurations are the same as those of the first embodiment.

The configuration described above reduces a difference between a detected in-focus position calculated from focus detection signals and the best in-focus position of the image signal, and enables a highly accurate or highly sensitive and fast focus detection.

As described above, the present invention achieves more stable and highly accurate focusing by acquiring a contrast evaluation value by using a more appropriate filter frequency band. In other words, the present invention allows the detected in-focus position and the focusing direction calculated from focus detection signals to be accurately detected independently from a current focus state, which enables a faster determination of the focusing direction, and a more highly accurate determination of the focusing point.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-104153, filed on May 20, 2014, which is hereby incorporated by reference wherein in its entirety.

1. An image pickup apparatus comprising:
a calculator configured to detect a defocus amount based on a contrast evaluation value of a synthesized signal, the synthesized signal being obtained by relatively shifting phases of passband signals of first and second signals through a predetermined frequency band and by synthesizing the passband signals; and
a controller capable of changing the predetermined frequency band.

2. The image pickup apparatus according to claim 1,
wherein the calculator calculates the defocus amount by a phase difference detection method using the first and second signals, and
wherein the controller changes the predetermined frequency band depending on the defocus amount.

3. The image pickup apparatus according to claim 1, wherein the controller selects one of a plurality of frequency bands as the predetermined frequency band.

4. The image pickup apparatus according to claim 1, further comprising:
a detector configured to generate a contrast evaluation value from a passband signal through one of a first frequency band and a second frequency band lower than the first frequency band, which is selected based on a detection result of the calculator,
wherein the detector generates the synthesized signal based on a passband signal through the second frequency band when the defocus amount is larger than a first predetermined value, and
wherein the detector generates the contrast evaluation value based on a passband signal through the first frequency band when the defocus amount is not larger than the first predetermined value.

5. The image pickup apparatus according to claim 2, wherein the calculator detects:
when the defocus amount detected by the phase difference detection method is larger than a second predetermined value, the defocus amount based on a third contrast evaluation value as a sum of a first contrast evaluation value as a product of a contrast evaluation value generated from a passband signal through a first frequency band with a first weight and a second contrast evaluation value as a product of a contrast evaluation value generated from a passband signal through a second frequency band with a second weight larger than the first weight; and
when the defocus amount detected by the phase difference detection method is not larger than the second predetermined value, the defocus amount based on a fourth contrast evaluation value as a product of a contrast evaluation value generated from a passband signal through the first frequency band with a third weight and a fifth contrast evaluation value as a product of a contrast evaluation value generated from a passband signal through a second frequency band with a fourth weight smaller than the third weight.

6. The image pickup apparatus according to claim 1, wherein the calculator detects the contrast evaluation value by a contrast detection method.

7. The image pickup apparatus according to claim 1, further comprising:
an image pickup element including first and second pixels sharing a single micro lens and configured to receive light passing through pupil regions of an optical system that are different from each other; and
a refocus signal generator configured to perform refocus processing on a first signal obtained from the first pixel and a second signal obtained from the second pixel to generate a refocus signal,
wherein the detector generates the contrast evaluation value based on the refocus signal.

8. The image pickup apparatus according to claim 7, further comprising a second focus detector configured to detect the defocus amount based on the contrast evaluation value.

9. The image pickup apparatus according to claim 8, further comprising a controller configured to perform focusing based on the defocus amount.

10. An image pickup apparatus comprising:
a detector configured to detect an image pickup state; and
a generator configured to generate a contrast evaluation value from a passband signal through one of a first frequency band and a second frequency band lower than the first frequency band, which is selected based on a detection result of the detector.

11. An image pickup apparatus comprising:
a detector configured to detect an image pickup state; and
a generator configured to generate a third contrast evaluation value as a sum of a first contrast evaluation value based on a passband signal through a first frequency band and a first weight and a second contrast evaluation value based on a passband signal through a second frequency band lower than the first frequency band and a second weight different from the first weight,
wherein the generator changes the first weight and the second weight based on a detection result of the detector.

12. The image pickup apparatus according to claim 10, wherein the generator generates the contrast evaluation value based on a passband signal through the second frequency band when having received an output signal from the detector, and generates the contrast evaluation value based on a passband signal through the first frequency band when not having received an output signal from the detector.

13. The image pickup apparatus according to claim 10, wherein the generator generates:
the contrast evaluation value based on a passband signal through the second frequency band when an output value from the detector is larger than a third predetermined value; and
the contrast evaluation value based on a passband signal through the first frequency band when the output value from the detector is not larger than the third predetermined value.

14. The image pickup apparatus according to claim 11, wherein the generator generates:
when having received an output signal from the detector, a third contrast evaluation value as a sum of a first contrast evaluation value as a product of a contrast evaluation value generated based on a passband signal through the first frequency band with a first weight and a second contrast evaluation value as a product of a contrast evaluation value generated based on a passband signal through the second frequency band with a second weight larger than the first weight; and
when not having received an output signal from the detector, a sixth contrast evaluation value as a sum of a fourth contrast evaluation value as a product of a contrast evaluation value generated based on a passband signal through the first frequency band with a third weight and a fifth contrast evaluation value as a product of a contrast evaluation value generated based on a passband signal through the second frequency band with a fourth weight smaller than the third weight.

15. The image pickup apparatus according to claim 11, wherein the generator generates:
when an output value from the detector is larger than a fourth predetermined value, a third contrast evaluation value as a sum of a first contrast evaluation value as a product of a contrast evaluation value generated based on a passband signal through the first frequency band with a first weight and a second contrast evaluation value as a product of a contrast evaluation value generated based on a passband signal through the second frequency band with a second weight larger than the first weight; and
when an output value from the detector is not larger than fourth predetermined value, a sixth contrast evaluation value as a sum of a fourth contrast evaluation value as a product of a contrast evaluation value generated based on a passband signal through the first frequency band with a third weight and a fifth contrast evaluation value as a product of a contrast evaluation value generated based on a passband signal through the second frequency band with a fourth weight smaller than the third weight.

16. The image pickup apparatus according to claim 10, wherein the image pickup state is a shaking state or a zooming state.

17. The image pickup apparatus according to claim 10, further comprising:
an image pickup element including first and second pixels sharing a single micro lens and configured to receive light passing through pupil regions of an optical system that are different from each other; and
a refocus signal generator configured to perform refocus processing on a first signal obtained from the first pixel and a second signal obtained from the second pixel to generate a refocus signal,
wherein the generator generates the contrast evaluation value based on the refocus signal.

18. The image pickup apparatus according to claim 17, further comprising a second focus detector configured to detect a defocus amount based on the contrast evaluation value.

19. The image pickup apparatus according to claim 18, further comprising a controller configured to perform focusing based on the defocus amount.

20. A method of controlling an image pickup apparatus, the method comprising the step of detecting a defocus amount based on a contrast evaluation value of a synthesized signal,
wherein the synthesized signal is obtained by relatively shifting phases of passband signals of first and second signals through a predetermined frequency band and by synthesizing the passband signals, and
wherein the predetermined frequency band is variable.

21. A method of controlling an image pickup apparatus, the method comprising the steps of:
detecting an image pickup state; and
generating a contrast evaluation value from a passband signal through one of a first frequency band and a second frequency band lower than the first frequency band, which is selected based on a detection result of the detecting step.

22. A method of controlling an image pickup apparatus, the method comprising the steps of:
detecting an image pickup state; and
generating a third contrast evaluation value as a sum of a first contrast evaluation value based on a passband signal through a first frequency band and a first weight and a second contrast evaluation value based on a passband signal through a second frequency band lower than the first frequency band and a second weight different from the first weight,
wherein the generating step changes the first weight and the second weight based on a detection result of the detecting step.

23. A non-transitory computer-readable storage medium storing a program that causes a computer to execute a method of controlling an image pickup apparatus, the control method comprising the step of detecting a defocus amount based on a contrast evaluation value of a synthesized signal,
wherein the synthesized signal is obtained by relatively shifting phases of passband signals of first and second signals through a predetermined frequency band and by synthesizing the passband signals, and
wherein the predetermined frequency band is variable.

24. A non-transitory computer-readable storage medium storing a program that causes a computer to execute a method of controlling an image pickup apparatus, the control method comprising the steps of:
detecting an image pickup state; and
generating a contrast evaluation value from a passband signal through one of a first frequency band and a second frequency band lower than the first frequency band, which is selected based on a detection result of the detecting step.

25. A non-transitory computer-readable storage medium storing a program that causes a computer to execute a method of controlling an image pickup apparatus, the control method comprising the steps of:
detecting an image pickup state; and
generating a third contrast evaluation value as a sum of a first contrast evaluation value based on a passband signal through a first frequency band and a first weight and a second contrast evaluation value based on a passband signal through a second frequency band lower than the first frequency band and a second weight different from the first weight,
wherein the generating step changes the first weight and the second weight based on a detection result of the detecting step.
